(19) United States
(12) Patent Application Publication
(10) Pub. No.: US 2007/0089026 A1
(43) Pub. Date: Apr. 19, 2007

(54) Coding circuit and coding apparatus

(75) Inventor: Kenji Uchida, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: YOKOGAWA ELECTRIC CORPORATION

(21) Appl. No.: 11/527,558

(22) Filed: Sep. 27, 2006

(30) Foreign Application Priority Data
Sep. 30, 2005 (JP) 2005-287213

(51) Int. Cl. H03M 13/00

(52) U.S. Cl. 714/758

(57) ABSTRACT

Disclosed is a coding circuit including: a holding unit to hold a first signal, and to output the held first signal as a fourth signal in synchronization with an input of a second signal and a third signal which respectively comprise one of two data produced by splitting a data for coding parallely and alternately into two; a first exclusive OR unit to calculate the exclusive OR of the second and fourth signals so as to output a fifth signal; a second exclusive OR unit to calculate the exclusive OR of the second and third signals so as to output an arithmetic result signal; and a third exclusive OR unit to calculate the exclusive OR of the fourth signal and the arithmetic result signal so as to output the first signal to be input to the holding unit.

### BACKGROUND OF THE INVENTION

1. Field of the Invention

This invention relates to a coding circuit and a coding apparatus for optical communication.

2. Description of Related Art

A conventional transmitter for a high-speed communication network of optical communication comprises an optical modulator which modulates laser light output from a light source in accordance with the digital data to be transmitted so as to output a light signal, amplifies the modulated light signal to transmit it to a destination through an optical fiber or the like. The phase modulation scheme for phase-modulating the laser light is employed as one of the modulation schemes for the optical modulator. The light is expressed by Equation (1) below.
y=A sin(ωt+φ) (1)

Where y is the amplitude of the light, A the maximum amplitude value, ω the angular frequency, t the time and φ the phase. In the phase modulation scheme, the phase φ assumes the value 0 or π rad in accordance with the phase modulation.

The phase modulation scheme includes PSK (phase shift keying) in which a signal including a data to be transmitted assumes values 0 and 1 to which the phase of 0 and π are assigned respectively. In this modulation scheme, however, the value 0 or 1 cannot be discriminated only from the phase-modulated optical signal. As a phase modulation scheme to improve this feature, DPSK (differential PSK) has been conceived.

FIG. 5 shows state transition in phase conversion by the DPSK scheme on an optical phase space. In FIG. 5, the ordinate represents the imaginary part and the abscissa represents the real part. In the DPSK scheme, as shown in FIG. 5, the phase is held as it is in the case where the signal having the data to be transmitted is 0 and the phase is shifted by π rad in the case where the signal having the data to be transmitted is 1. According to the DPSK scheme, the value of the data (0 or 1) can be determined only from the phase-modulated optical signal. The phase modulation of the DPSK scheme realizes easily by applying a precoded control voltage to a LN (LiNbO₃) modulator as an optical modulator. A configuration to generate this control voltage by a single exclusive OR (XOR) element has been conceived (for example, JP No. 2002-64574A).

FIG. 6 shows a configuration of a conventional coding circuit 80. As shown in FIG. 6, the coding circuit 80 includes an XOR circuit 81 and a delay element 82. In the coding circuit 80, a signal S31 having the data to be transmitted is input to the XOR circuit 81, and a signal S1 output from the XOR circuit 81 is delayed by one bit by the delay element 82 and is input to the XOR circuit 81 as a signal S32. In the XOR circuit 81, the signals S31 and S32 are subjected to the exclusive OR operation and a signal S1 is output as a control signal. The truth table of the exclusive OR operation is shown in Table 1. This indicates that the modulation rule of the DPSK scheme is satisfied.

TABLE 1

| SIGNAL S31 | SIGNAL S32 | SIGNAL S1 |
|---|---|---|
| 0 | 0 | 0 (0 rad) |
| 0 | 1 | 1 (π rad) |
| 1 | 0 | 1 (π rad) |
| 1 | 1 | 0 (0 rad) |

In Table 1, 0 and π rad are the phases assigned to the input light in the LN modulator.

Assume that (+) is a symbol of the exclusive OR operation, and then the signal S1 is arithmetically expressed by Equation (2) below.
(S1)ᵢ=(S31)ᵢ(+)(S1)ᵢ₋₁=(S31)ᵢ(+)(S31)ᵢ₋₁(+)(S1)ᵢ₋₂= . . . =(S31)ᵢ(+)(S31)ᵢ₋₁(+) . . . (+)(S31)₁(+)(S1)₀ (2)

In the optical communication techniques, demand for speed-up is on the increase, and in recent years, the bit rate of as high as 43 Gb/s has been required. It takes about 23 ps to transmit one bit at the bit rate of as high as 43 Gb/s Assuming that the response speed of the XOR circuit 81 of the coding circuit 80 is about 15 ps, delay time T of the delay element 82 is calculated as about 8 ps. This delay time of 8 ps is too short to use a circuit such as a FF (flip-flop) which synchronizes with the clock signal. Therefore, the delay time of 8 ps is only attained with a simple circuit such as a transmission line or an inverter.

Unless the clock signal is synchronized, however, an error occurs in the case where the signal of the data to be transmitted continues 1. Specifically, when the signal is successive is, the signal S1 is oscillated in accordance with the total time determined by the XOR circuit 81 and the delay element 82. Assuming that this oscillation period deviates by 1 ps from the time (23 ps) required to transmit one bit, the logic would be inverted by a succession of about eleven 1 s. In the real system, it is difficult to suppress the delay error to not more than 1 ps. In other words, the direct preceding by the coding circuit 80 of the signal of 43 Gb/s having the data to be transmitted is difficult to realize due to a problem in the electrical circuit operation.

Also, a series of data signals to be transmitted at high bit rate can be obtained generally by multiplexing signals of lower bit rate.

FIG. 7 shows a configuration of the conventional coding apparatus 200. As shown in FIG. 7, the coding apparatus 200 includes 2-to-1 multiplexers (MUX) 20, 30 and 70 and a coding circuit 80. The coding signals S2 and S3 obtained by splitting the data to be transmitted are output as a signal S6 of a double bit rate (half period) having the data of the signals S2 and S3 synthesized by the multiplexer 20. In similar fashion, the coding signals S4 and S5 are output as a signal S7 of a double bit rate having the data of the signals S4 and S5 synthesized by the 2-to-1 multiplexer 30. The signals S6 and S7 are output as a half-period signal S31 synthesized by the 2-to-1 multiplexer 70. The signals S2, S3, S4 and S5 have a bit rate one fourth of that of the signal S31. In view of the fact that the signal S31 input to the coding circuit 80 is (always) required to have a high bit rate, however, the coding could not be realized.

### SUMMARY OF THE INVENTION

It is an object of the present invention is to provide a coding circuit and a coding apparatus by which the preceding of a signal having high bit rate can be carried out stably in the DPSK optical modulation or the like.

In order to attain the above object, according to a first aspect of the invention, a coding circuit comprises: a holding unit to hold a first signal, and to output the held first signal as a fourth signal in synchronization with an input of a second signal and a third signal which respectively comprise one of two data produced by splitting a data for coding parallely and alternately into two; a first exclusive OR unit to calculate the exclusive OR of the second and fourth signals so as to output a fifth signal; a second exclusive OR unit to calculate the exclusive OR of the second and third signals so as to output an arithmetic result signal; and a third exclusive OR unit to calculate the exclusive OR of the fourth signal and the arithmetic result signal so as to output the first signal to be input to the holding unit.

As a result, in the optical phase modulation by the DPSK scheme or the like, the second and third signals are coded and can be output as fourth and fifth signals, so that the fourth and fifth signals can be synthesized to a double bit rate. Thus, the precoding to obtain a signal having a high bit rate can be performed in stable manner. At the same time, the feedback loop including the holding means can be routed only through a first exclusive OR means, thereby making it possible to secure a sufficient operation time of the holding means.

According to a second aspect of the invention, a coding circuit comprises: a holding unit to hold a first signal, and to output the held first signal as a fourth signal in synchronization with an input of a second signal and a third signal which respectively comprise one of two data produced by splitting a data for coding parallely and alternately into two; a first exclusive OR unit to calculate the exclusive OR of the second and fourth signals so as to output a fifth signal; and a second exclusive OR unit to calculate the exclusive OR of the third and fifth signals so as to output the first signal to be input to the holding unit.

As a result, in the optical phase modulation by the DPSK scheme or the like, the second and third signals are coded and can be output as the fourth and fifth signals. By thus obtaining the fourth and fifth signals at a double bit rate by synthesis, the preceding to obtain a signal of a high bit rate can be performed in stable fashion. At the same time, the number of outputs of the holding means can be reduced to two including the output of the fourth signal and the output of the first exclusive OR means, thereby reducing the load on the signal output of the holding means.

Preferably, the coding circuit further comprises: a first delay unit to delay the fourth signal by a period for synchronization with the fifth signal.

As a result, the fourth and fifth signals can be synchronized with each other.

Preferably, the coding circuit further comprises: a first synchronizing unit to synchronize the second signal with the third signal by synchronization with an input of a clock signal of the same frequency as bit rate of the second and third signals, wherein the holding unit outputs the first signal as the fourth signal in synchronization with an input of the clock signal.

As a result, the second and third signals can be synchronized with each other based on the clock signal, and even in the case where the bits of the same value of the second or third signal form an arbitrary long train, a logic error is prevented.

Preferably, the coding circuit further comprises: a second synchronizing unit to synchronize the fourth and fifth signals in synchronism with the input of the clock signal.

As a result, the fourth and fifth signals can be synchronized with each other based on the clock signal.

Preferably, the coding circuit further comprises second delay unit to delay a clock signal by a predetermined period, wherein the second synchronizing unit synchronizes the fourth signal with the fifth signal by synchronization with an input of the clock signal delayed by the second delay unit.

As a result, the operation margin of the second synchronizing means can be widened.

According to a third aspect of the invention, a coding apparatus comprises: the coding circuit according to claim 1; a first switching unit to switch a sixth signal and a seventh signal so as to output the second signal having data of the sixth and seventh signals and a bit rate twice as high as the sixth and seventh signals, the sixth and seventh signals respectively comprising one of two data produced by splitting a data of the second signal parallely and alternately into two; a second switching unit to switch an eighth signal and a ninth signal so as to output the third signal having data of the eighth and ninth signals and a bit rate twice as high as the eighth and ninth signals, the eighth and ninth signals respectively comprising one of two data produced by splitting a data of the third signal parallely and alternately into two; and a third switching unit to switch the fourth signal and the fifth signal so as to output a tenth signal having data of the fourth and fifth signals and a bit rate twice as high as the fourth and fifth signals.

As a result, the sixth, seventh, eighth and ninth signals can be precoded to form a tenth signal having a quadruple bit rate. Thus, the precoding to obtain a signal having a high bit rate can be performed in stable fashion.

### BRIEF DESCRIPTION OF THE DRAWINGS

The present invention will become more fully understood from the detailed description given hereinbelow and the appended drawings which given by way of illustration only, and thus are not intended as a definition of the limits of the present invention, and wherein;

FIG. 1 is a block diagram showing a configuration of the LN modulator 10;

FIG. 2 is a block diagram showing a configuration of the coding apparatus 100 according to an embodiment of the invention;

FIG. 3 is a diagram showing a configuration of the cording circuit 40 according to an embodiment of the invention;

FIG. 4 is a diagram showing a configuration of the coding circuit 40A according to a modification of the embodiment of the invention;

FIG. 5 is a state transition diagram showing the phase conversion according to the DPSK scheme in the optical phase space;

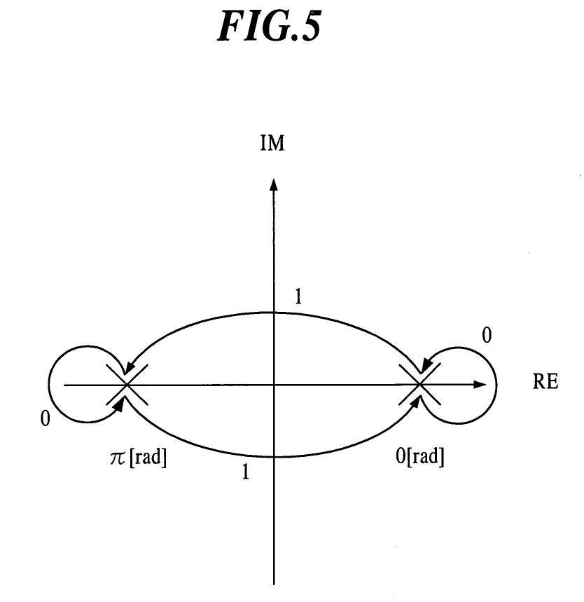

FIG. 6 is a diagram showing a configuration of the conventional coding circuit 80; and

FIG. 7 is a block diagram showing a configuration of the conventional coding apparatus 200.

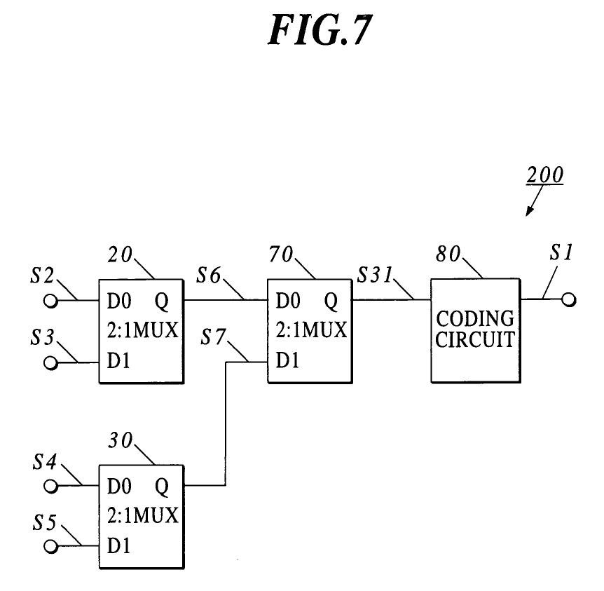

### DETAILED DESCRIPTION OF PREFERRED EMBODIMENTS

Embodiments of the invention are explained in detail below with reference to the accompanying drawings. The scope of this invention, however, is not limited to the shown examples.

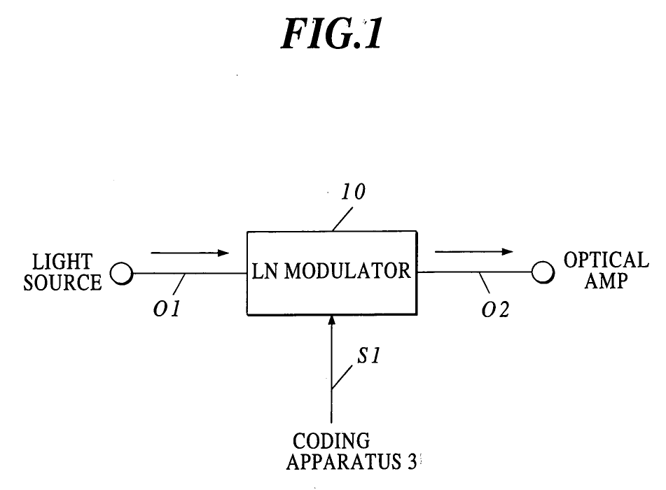

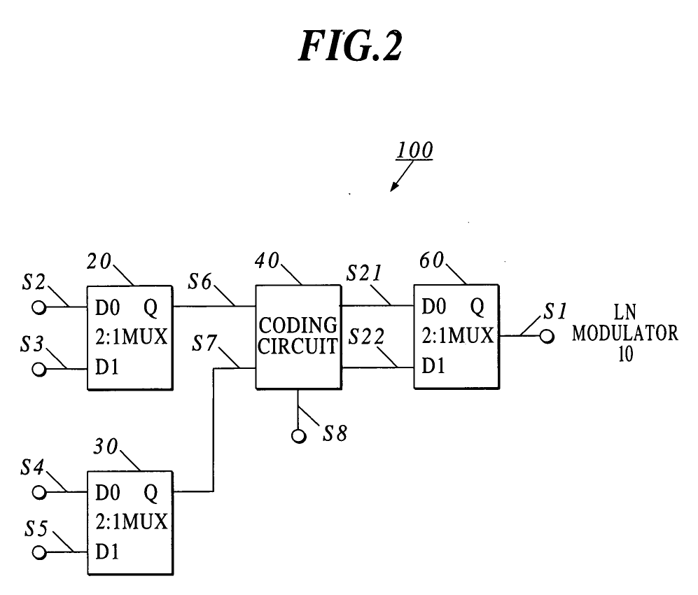

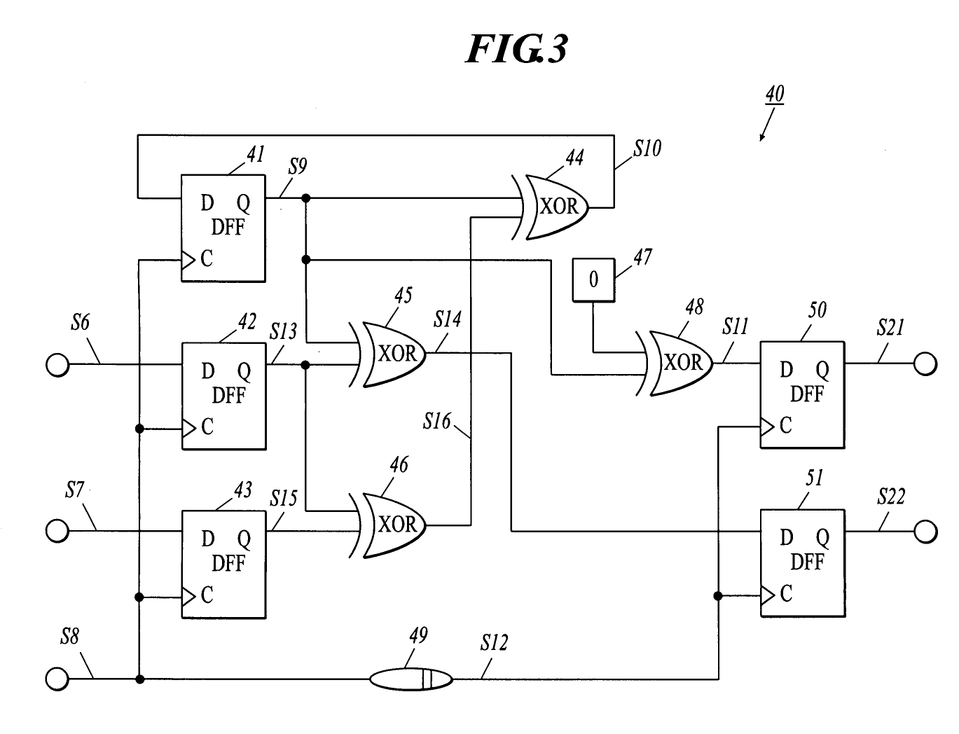

First, with reference to FIGS. 1 to 3, a configuration of the apparatus according to an embodiment is explained. The component elements identical to those of the conventional technique described above are designated by the same reference numerals, respectively, and not explained any more. FIG. 1 shows a configuration of the LN modulator 10. FIG. 2 shows a configuration of the coding apparatus 100 according to this embodiment. FIG. 3 shows a configuration of the coding circuit 40 according to this embodiment.

As shown in FIG. 1, an optical transmitter not shown includes the LN modulator 10. In the LN modulator 10, a laser optical signal O1 is input, and based on the signal S1 as a control signal for coding corresponding to the data output and to be transmitted from the coding apparatus 100 described later, the optical signal O1 is output as an optical signal O2 containing the phase-modulated data of the optical signal O1 to be transmitted. The optical signal O1 is a laser light output from a light source not shown and constitutes a carrier with the phase thereof always adjusted to 0 rad. The optical signal O2 is amplified by an optical amplifier or the like not shown, and transmitted through a medium such an optical fiber to a destination such as a receiver. Specifically, the LN modulator 10 outputs the optical signal O2 by setting the optical signal O1 to 0 rad in the case where the signal S1 is 0 and to π rad in the case where the signal S1 is 1.

As shown in FIG. 2, the coding apparatus 100 for carrying out the phase conversion by the DPSK scheme includes a 2-to-1 multiplexer 20 as a first switching means, a 2-to-1 multiplexer 30 as a second switching means, a 2-to-1 multiplexer 60 as a third switching means and a coding circuit 40.

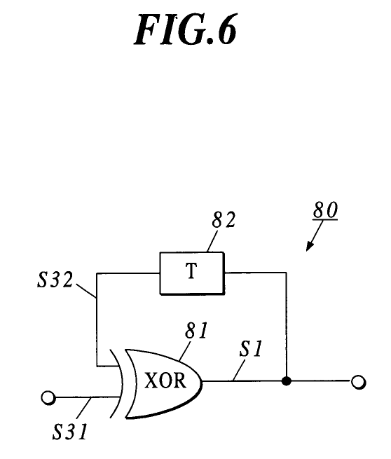

The coding apparatus 100 is for coding in the phase conversion according to the DPSK scheme and outputs the signal S1 as a control voltage of the LN modulator 10 by coding the signal (signal S0) having the data to be transmitted. The logic operation of the coding circuit 40 is similar to that of the coding circuit 80 shown in FIG. 6. Specifically, the signal train of the signal S0 and the signal train after coding by the coding circuit 40 are related to each other as shown in Table 2 below. In Table 2, the signal (train) is assumed to pass along the time axis from left to right as in the other tables. Also, assume that the initial value of the signal train after coding happens to be 0.

TABLE 2

| | |
|---|---|
| SIGNAL S0 | 1 0 0 0 1 0 0 1 1 0 1 0 1 1 1 1 . . . |
| CODED SIGNAL | 0 1 1 1 1 0 0 0 1 0 0 1 1 0 1 0 1 . . . |

The 2-to-1 multiplexers 20, 30, 60 each output two input signals alternately (selectively) thereby to produce an output signal of a double bit rate having the temporally serial alternate data of the two input signals. The 2-to-1 multiplexer 20 supplied with the signals S2, S3 as the sixth and seventh signals outputs the signal S6 as a second signal of a double bit rate having the data of the signals S2, S3. The 2-to-1 multiplexer 30 supplied with the signals S4, S5 as eighth and ninth signals outputs the signal S7 as a third signal of a double bit rate having the data of the signals S4, S5.

The signals S2, S3, S4, S5 are multiplexed and constitute the signal S0 to be transmitted. Specifically, the signals S2, S3, S4, S5 are split into the signal train of the signals S2, S3, S4, S5 shown Table 3 below corresponding to the signal train of the signal S0 shown in Table 2 above.

TABLE 3

| | |
|---|---|
| SIGNAL S2 | 1 1 1 1 . . . |
| SIGNAL S3 | 0 0 0 1 . . . |
| SIGNAL S4 | 0 0 1 1 . . . |
| SIGNAL S5 | 0 1 0 1 . . . |

Also, in accordance with the signal train of the signals S2, S3, S4, S5 shown in Table 3, above, the signal train of the signal S6 (=signal S13 described later) and the signal S7 (=signal S15 described later) shown in Table 4 below is output.

TABLE 4

| | |
|---|---|
| SIGNAL S6 (S13) | 1 0 1 0 1 1 1 1 . . . |
| SIGNAL S7 (S15) | 0 0 0 1 0 0 1 1 . . . |

The coding circuit 40 supplied with the signals S6, S7, S8 outputs the signals S21, S22 as the fourth and fifth signals, respectively, by precoding the signals S6, S7 based on the signal S8 as a clock signal. The signal S8 is generated by a clock signal generator not shown.

The 2-to-1 multiplexer 60 supplied with the signals S21, S22 outputs the signal S1 as a tenth signal having the digital data and double in bit rate. The signal S1 has a bit rate twice as high as the signals S6, S7, S21, S22, i.e. a bit rate four times as high as the signals S2, S3, S4, S5. Assuming that the signals S1 is 40 Gb/s, the signals S6, S7, S21, S22 are 20 Gb/s and the signals S2, S3, S4, S5 are 10 Gb/s, for example, the signal S8 has a frequency corresponding to 20 Gb/s.

As shown in FIG. 3, the coding circuit 40 includes a DFF (delay flip-flop) circuit 41 as a holding means, DFF circuits 42, 43 as a first sync means, an XOR circuit as a first exclusive OR means, an XOR circuit 45 as a second exclusive OR means, an XOR circuit 46 as a third exclusive OR means, a signal source 47, an XOR circuit 48 as a first delay means, a delay element 49 as a second delay means and DFF circuits 50, 51 as a second sync means.

The DFF circuit holds the input signal in accordance with the rise of the input clock signal and outputs, as an output signal, the input signal held to the rise of the next clock signal. The DFF circuit 41 is such that the signal S8 is input to the clock terminal, the signal S10 as the first signal is input to the data terminal while holding the signal S10, and based on the signal S8, the held signal S10 is output from the output terminal as a signal S9 constituting a fourth signal. The DFF circuit 42, on the other hand, is such that the signal S8 is input to the clock terminal, the signal S6 is input to the data terminal thereby to hold the signal S6, and based on the signal S8, the held signal S6 is output from the output terminal as a signal S13. Also, the DFF circuit 43 is such that the signal S8 is input to the clock terminal, the signal S7 is input to the data terminal thereby to hold the signal S7, and based on the signal S8, the held signal S7 is output from the output terminal as a signal S15. The signals S6, 7, S10 can be synchronized (the signals S9, S13, S15 can be synchronized) by the DFF circuits 41, 42, 43.

The XOR circuit 44 supplied with the signal S9 and the signal S16 as an arithmetic result signal calculates the exclusive OR of the signals S9, S16 and outputs the resultant signal S10. The XOR circuit 45 supplied with the signals S9, S13 calculates the exclusive OR of the signals S9, S13 and outputs the signal S14 as a fifth signal. The XOR circuit 46 supplied with the signals S13, S15 calculates the exclusive OR of the signals S13, S15 and outputs the signal S16.

The signal source 47 outputs a signal assuming a constant value of zero. The XOR circuit 48 supplied with the zero signal from the signal source 47 and the signal S9 calculates the exclusive OR of the zero signal and the signal S9 and outputs the signal S11. Specifically, the signal S9 is output without changing the value as a signal S11. The signal source 47 and the XOR circuit 48 are provided to delay and output the input signal, to which the configuration is not limited. In place of the signal source 47 and the XOR circuit 48, for example, the delay line or the delay through the gate of an active element can alternatively be used.

The delay element 49 delays the signal S8 and outputs the signal S12. The delay time of the delay element 49 corresponds to one stage of the XOR circuit. The delay element 49 is constituted as a delay line, to which the configuration is not limited. A configuration can be employed, for example, which uses the delay through the gate of an active element or by the XOR circuit supplied with the zero signal.

The DFF circuit 50 is such that the signal S12 is input to the clock terminal, the signal S11 is input to the data terminal while the signal S11 is held, and based on the signal S12, the held signal S11 is output from the output terminal as signal S21. The DFF circuit 51 is such that the signal S12 is input to the clock terminal, the signal S14 is input to the data terminal while the signal S14 is held, and based on the signal S12, the held signal S14 is output from the output terminal as signal S22. The signals S11, S14 (the signals S21, S22) can be synchronized by the DFF circuits 50, 51.

The signals S21, S22 are desirably output at the same time, and therefore the signals S11, S14 are also desirably prepared at the same time. The signal S14 is output delayed by one stage of the XOR circuit 45 after the change of the signal S9. As a result, the delay time is adjusted by interposing the XOR circuit 48 between the signals S9 and S14.

The signal S10 input to the DFF circuit 41 outputting the signal S9 is generated through at least one XOR circuit from the signal S9. Until the signal S10 is settled, the next signal S8 cannot be input. Further, the signals S11, S14 are passed through the only one XOR circuit 45 or 48 from the DFF circuit 41. Without interposing the delay element 49 between the signals S8, S12, therefore, the coding circuit 40 operates. For practical purposes, however, the interposition of the delay element 49 desirably widens the operation margin of the DFF circuits 50, 51 outputting the signals S21, S22.

Next, the operation of the coding circuit 40 is explained. In the coding circuit 40, three operations are repeated. In the first operation, the value (phase state) of the signal S9 currently held in the DFF circuit 41 is output as signal S21 through the XOR circuit 48 and the DFF circuit 50.

In the second operation, the XOR circuit 45 operates in such a manner that in the case where the next signal S13 is 0 in value, the signal S9 constituting the signal S14 is output as signal S22 through the DFF circuit 51, while in the case where the value of the signal S13 is 1, the signal S9 is inverted into the signal S14 and output as signal S22 through the DFF circuit 51. Specifically, like in the coding circuit 80 shown in FIG. 6, the preceding signal S21 (S11) and the next signal S13 are subjected to the exclusive OR operation thereby to produce the signal S22.

In the third operation, the XOR circuit 46 outputs the signal S16 as the exclusive OR of the next signals S13, S15, and the XOR circuit 44 outputs the signal S10 as the exclusive OR of the signal S9 currently held in the DFF circuit 41 and the next signal S16, which signal S10 is input to the DFF circuit 41. In this operation, like in the coding circuit 80 shown in FIG. 6, the signal S10 calculated as an exclusive OR of the preceding signal S14 (S22) and the next signal S15 is desirably input to and held in the DFF circuit 41. The signal S10 is calculated by Equation (3) below. The symbol (+) indicates the exclusive OR.
S10=S14(+)S15=(S9(+)S13)(+)S15=S9(+)(S13(+)S15)=S9(+)S16 (3)
As a result, the signal S10 is obtained as the exclusive OR of the signals S9, S16.

In the coding circuit 40, the first to third operations described above are repeated thereby to produce a signal train of the signals S21, S22. In accordance with the signal train of the signals S6, S7 shown in Table 4, for example, the first to third operations of the coding 40 are performed thereby to output the signal train of the signals S21 (=S9, S11), S22 (=S14) shown in Table 5.

TABLE 5

| | |
|---|---|
| SIGNAL S21 (S9, S11) | 0 1 1 0 1 0 1 1 . . . |
| SIGNAL S22 (S14) | 1 1 0 0 0 1 0 0 . . . |

Also, the 2-to-1 multiplexer 60 supplied with the signal train of the signals S21, S22 shown in Table 5 outputs the signal train of the signal S1 shown in Table 6 below. The signal train of the signal S1 shown in Table 6 is understood to be identical with the signal train after coding the signal S0 shown in Table 2 above.

TABLE 6

| | |
|---|---|
| SIGNAL S1 | 0 1 1 1 1 0 0 0 1 0 0 1 1 0 1 0 1 . . . |

As described above, according to this embodiment, the phase modulation of the light according to the DPSK scheme is carried out in such a manner that the coding circuit 40 codes the signals S6, S7 thereby to output the signals S21, S22, which are combined to double the bit rate, thereby making possible stable preceding of a signal of high bit rate.

Also, the feedback loop including the DFF circuit 41 can be passed only through the signal S9, the XOR circuit 44 and the signal S10, and therefore a sufficient length of time to operate the DFF circuit 41 can be secured.

Specifically, the stumbling block to realizing a high bit rate is the place where the feedback is configured, i.e. the portion corresponding to the signal S9, the XOR circuit 44 and the signal S10. Assuming that the signals S6, S7 have the bit rate of 27 Gb/s or one half the bit rate of 43 Gb/s, the propagation of one bit requires the time of 46 ps. Assume that the time from the output of the signal S9 of the DFF circuit 41 to the output of the signal S10 of the XOR circuit 44 (response time of the XOR circuit 44) is about 15 ps. The set-up time and the hold time of about 31 ps can be assigned to the DFF circuit 41, so that the time sufficiently long to operate the DFF circuit 41 can be secured.

Also, the signals S21, S22 can be synchronized by the XOR circuit 48.

The signals S6, S7 can be synchronized by the DFF circuits 42, 43 based on the clock signal, and even in the case where an arbitrarily long train of bits of the same value is formed by the signals S6, S7, a logic error can be prevented.

Also, the signals S21, S22 can be synchronized by the DFF circuits 50, 51 based on the clock signal. Further, the operation margin of the DFF circuits 50, 51 can be widened by the delay element 49.

The coding apparatus 100 can output the signal S1 having a quadruple bit rate by preceding the signals S2, S3, S4, S5, thereby making it possible to precode a signal at a high bit rate.

(Modification)

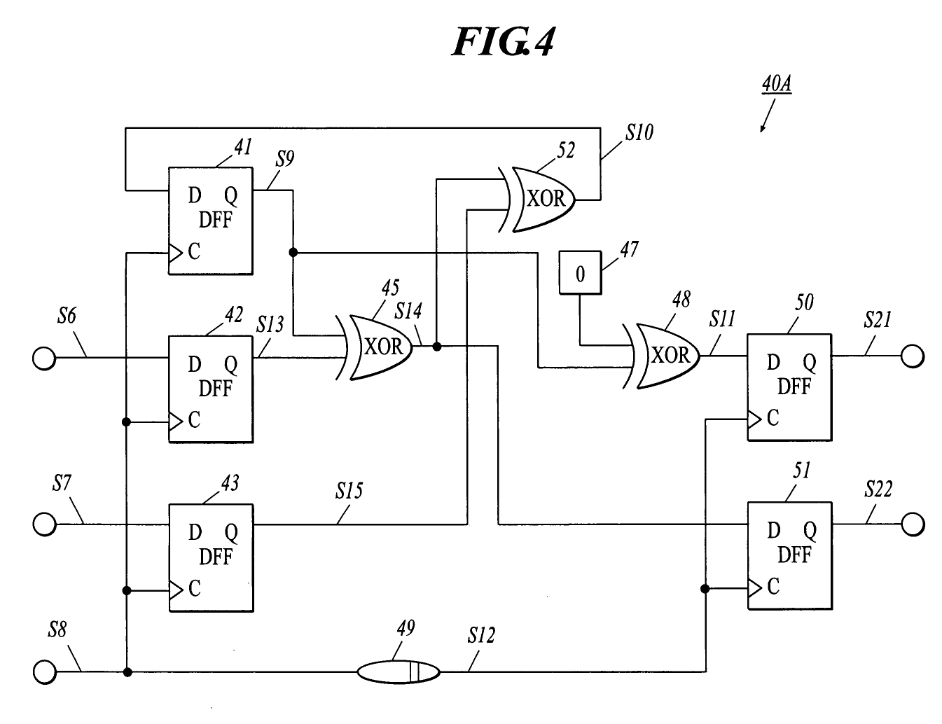

With reference to FIG. 4, a modification of the aforementioned embodiment is explained. FIG. 4 shows a configuration of the coding circuit 40A according to this modification. In this modification, the portions different from those of the embodiment described above are mainly explained.

According to this modification, the coding apparatus 100 according to the aforementioned embodiment includes a coding circuit 40A in place of the coding circuit 40. As shown in FIG. 4, the coding circuit 40A includes DFF circuits 41, 42, 43, an XOR circuit 45, a signal source 47, an XOR circuit 48, a delay element 49, DFF circuits 50, 51 and an XOR circuit 52 as a second exclusive OR means.

The XOR circuit 52 supplied with the signals S14, S15 outputs the signal S10 by calculating the exclusive OR of the signals S14, S15. Also, like in the coding circuit 40, the delay element 49 may be done without.

The operation of the coding circuit 40A is similar to the first and second operations of the coding circuit 40 according to the embodiment described above. Unlike the third operation according to the embodiment described above in which the signal S10 is obtained by the exclusive OR operation of the signals S9, S16 in the coding circuit 40, this modification is such that the signal S10 is obtained by the exclusive OR operation directly performed on the signals S14, S15 in the XOR circuit 52, which signal S10 is input to the DFF circuit 41.

According to this modification, like in the embodiment described above, the phase modulation of the light according to the DPSK scheme is carried out in such a manner that the coding circuit 40A codes the signals S6, S7 and outputs the signals S21, S22. By synthesizing the signals S21, S22 while doubling the bit rate, the preceding to obtain a signal of high bit rate can be performed in stable fashion.

According to the embodiment described above, the DFF circuit 41 fans out to three circuits including the XOR circuits 44, 45, 48. According to this modification, on the other hand, the DFF circuit 41 fans out to two circuits including the XOR circuits 48, 52, thereby reducing the output burden of the signal of the DFF circuit 41.

Although the embodiment described above is so configured that the feedback loop including the DFF circuit 41 passes only through the signal S9, the XOR circuit 44 and the signal S10, this modification is so configured that the feedback loop including the DFF circuit 41 is formed through the signal S9, the XOR circuit 45, the signal S14, the XOR circuit 52 and the signal S10 in that order. Assume, therefore, that as described specifically in the embodiment above, the time required for propagation of one bit is 46 ps and the response time of the XOR circuit is 15 ps. Then, the time available for the DFF circuit 41 (set-up time and hold time) is only 16 (=46−2×15) ps, and the operation of the DFF circuit 41 becomes difficult. Nevertheless, this time length is not a value making the DFF circuit 41 inoperable.

The embodiment and the modification described above are only an example of the coding circuit and the coding apparatus according to the invention, and the invention is not limited to them.

For example, in spite of the forgoing description of the coding apparatus 100 including the coding circuits 40, 40A and the 2-to-1 multiplexers 20, 30, 60 provided separately from each other, the invention is not limited to such configuration, and an IC (integrated circuit) chip or the like can be employed in which the coding circuit 40 or 40A and the 2-to-1 multiplexers 20, 30, 60 are integrated with each other.

Although the embodiment and the modification described above refer to the coding circuits 40, 40A and the coding apparatus 100 for performing the precoding in the phase modulation according to DPSK scheme, the invention is not limited to such configuration. Instead, the aforementioned configuration can be used as a partial application of the coding circuit for precoding by the duobinary modulation scheme.

The other detailed configuration and the detailed operation of the coding circuit and the coding apparatus according to the aforementioned embodiment can be appropriately modified without departing from the spirit and scope of the invention.

The entire disclosure of Japanese Patent Application No. 2005-287213 filed on Sep. 30, 2005, including description, claims, drawings and summary are incorporated herein by reference in its entirety.

What is claimed is:

1. A coding circuit comprising:
a holding unit to hold a first signal, and to output the held first signal as a fourth signal in synchronization with an input of a second signal and a third signal which respectively comprise one of two data produced by splitting a data for coding parallely and alternately into two;
a first exclusive OR unit to calculate the exclusive OR of the second and fourth signals so as to output a fifth signal;
a second exclusive OR unit to calculate the exclusive OR of the second and third signals so as to output an arithmetic result signal; and
a third exclusive OR unit to calculate the exclusive OR of the fourth signal and the arithmetic result signal so as to output the first signal to be input to the holding unit.

2. A coding circuit comprising:
a holding unit to hold a first signal, and to output the held first signal as a fourth signal in synchronization with an input of a second signal and a third signal which respectively comprise one of two data produced by splitting a data for coding parallely and alternately into two;
a first exclusive OR unit to calculate the exclusive OR of the second and fourth signals so as to output a fifth signal; and
a second exclusive OR unit to calculate the exclusive OR of the third and fifth signals so as to output the first signal to be input to the holding unit.

3. The coding circuit according to claim 1, further comprising: a first delay unit to delay the fourth signal by a period for synchronization with the fifth signal.

4. The coding circuit according to claim 1, further comprising: a first synchronizing unit to synchronize the second signal with the third signal by synchronization with an input of a clock signal of the same frequency as bit rate of the second and third signals,
wherein the holding unit outputs the first signal as the fourth signal in synchronization with an input of the clock signal.

5. The coding circuit according to claim 4, further comprising: a second synchronizing unit to synchronize the fourth and fifth signals in synchronism with the input of the clock signal.

6. The coding circuit according to claim 5, further comprising a second delay unit to delay a clock signal by a predetermined period,
wherein the second synchronizing unit synchronizes the fourth signal with the fifth signal by synchronization with an input of the clock signal delayed by the second delay unit.

7. A coding apparatus comprising:
the coding circuit according to claim 1;
a first switching unit to switch a sixth signal and a seventh signal so as to output the second signal having data of the sixth and seventh signals and a bit rate twice as high as the sixth and seventh signals, the sixth and seventh signals respectively comprising one of two data produced by splitting a data of the second signal parallely and alternately into two;
a second switching unit to switch an eighth signal and a ninth signal so as to output the third signal having data of the eighth and ninth signals and a bit rate twice as high as the eighth and ninth signals, the eighth and ninth signals respectively comprising one of two data produced by splitting a data of the third signal parallely and alternately into two; and
a third switching unit to switch the fourth signal and the fifth signal so as to output a tenth signal having data of the fourth and fifth signals and a bit rate twice as high as the fourth and fifth signals.

8. The coding circuit according to claim 2, further comprising: a first delay unit to delay the fourth signal by a period for synchronization with the fifth signal.

9. The coding circuit according to claim 2, further comprising: a first synchronizing unit to synchronize the second signal with the third signal by synchronization with an input of a clock signal of the same frequency as bit rate of the second and third signals,
wherein the holding unit outputs the first signal as the fourth signal in synchronization with an input of the clock signal.

10. The coding circuit according to claim 9, further comprising: a second synchronizing unit to synchronize the fourth and fifth signals in synchronism with the input of the clock signal.

11. The coding circuit according to claim 10, further comprising a second delay unit to delay a clock signal by a predetermined period,
wherein the second synchronizing unit synchronizes the fourth signal with the fifth signal by synchronization with an input of the clock signal delayed by the second delay unit.

12. A coding apparatus comprising:
the coding circuit according to claim 2;
a first switching unit to switch a sixth signal and a seventh signal so as to output the second signal having data of the sixth and seventh signals and a bit rate twice as high as the sixth and seventh signals, the sixth and seventh signals respectively comprising one of two data produced by splitting a data of the second signal parallely and alternately into two;
a second switching unit to switch an eighth signal and a ninth signal so as to output the third signal having data of the eighth and ninth signals and a bit rate twice as high as the eighth and ninth signals, the eighth and ninth signals respectively comprising one of two data produced by splitting a data of the third signal parallely and alternately into two; and
a third switching unit to switch the fourth signal and the fifth signal so as to output a tenth signal having data of the fourth and fifth signals and a bit rate twice as high as the fourth and fifth signals.
